(19) United States
(12) Patent Application Publication
(10) Pub. No.: US 2007/0154638 A1
(43) Pub. Date: Jul. 5, 2007

(54) CHEMICAL VAPOR DEPOSITION METHOD

(76) Inventor: Dong Ho You, Chungbuk (KR)

Correspondence Address: SHERR & NOURSE, PLLC, 620 HERNDON PARKWAY, SUITE 200, HERNDON, VA, 20170, US

(21) Appl. No.: 11/617,084

(22) Filed: Dec. 28, 2006

(30) Foreign Application Priority Data
Dec. 29, 2005 (KR) 10-2005-0133832

(51) Int. Cl. C23C 16/00

(52) U.S. Cl. 427/248.1

(57) ABSTRACT

Disclosed is a chemical vapor deposition method capable of raising the pressure in a chamber to a base pressure without generating particles, before a main process forming an insulation layer on a substrate. The method comprises the steps of: (1) stabilizing a chamber in which a substrate is loaded on a heater by introducing a gas into the chamber; (2) increasing the pressure in the chamber to a base pressure by gradually closing a throttle valve; (3) stabilizing the base pressure in the chamber; and (4) forming an insulation film on the substrate by injecting a film forming gas into the chamber.

The present application claims priority under 35 U.S.C. 119 and 35 U.S.C. 365 to Korean Patent Application No. 10-2005-0133832 (filed on Dec. 29, 2005), which is hereby incorporated by reference in its entirety.

### BACKGROUND AND DESCRIPTION

In general, methods for forming a film on a wafer include a Low Pressure CVD (LPCVD) method, an Atmospheric Pressure CVD (APCVD) method, and a Sub-Atmospheric CVD (SACVD) method.

The LPCVD method is performed at a pressure of about 10% of the atmospheric pressure. The APCVD method is performed at 760 torr. The SACVD is performed at a pressure higher than in the LPCVD method and lower than in the APCVD method, for example, 100 to 700 torr.

Hereinafter, a chemical vapor deposition method will be described with reference to the accompanying drawings.

FIG. 1 is a schematic view showing gas flow when the base pressure of the chemical vapor deposition process is regulated. Table 1 is a detailed example of process conditions.

The chemical vapor deposition process shown in FIG. 1 relates to forming an insulation layer using the SACVD method.

As shown in FIG. 1 and Table 1, the chemical vapor deposition process includes the steps of: (1) stably introducing a gas into a chamber 10 in which a substrate 1 is loaded on the upper portion of the heater 11 (1. STAB (Stability)), (2) increasing the pressure in the chamber to 160 torr, with the throttle valve 13 closed in the pumping line 12 (2. P-Ramp); (3) stabilizing the pressure in the chamber (3. P STAB), and forming an insulation film on the substrate 1 by injecting a film forming gas into the chamber 10.

In the SACVD process, if the substrate 1 is positioned in the process chamber 10, the base pressure is regulated to between 100 to 200 torr to regulate the pressure value in the chamber 10 before a main process for forming the insulation layer is performed, and the pressure is raised to 200 to 750 torr.

The pressure in the chamber 10 is regulated to the base pressure, then the pressure is raised, with the throttle valve 13 being completely closed, after the gas is introduced into the chamber. However, the injected gas makes contact with the throttle valve 13 in the pumping line, and the gas flows back into the chamber.

If the gas introduced into the pumping line 12 flows back into the chamber, particles in the pumping line 12 are introduced into the chamber 10 together with the gas, which may deposit on the substrate 1.

The particles are very small (smaller than 0.1 μm) circular bodies which lower the yield of the substrate.

TABLE 1

| | Step number, name | | | |
|---|---|---|---|---|
| | 1. STAB | 2. P-Ramp | 3. P STAB | 5. Dep |
| Step selection | ABCDEF So Far = Any | ABCDEF So Far = Any | ABCDEF So Far = Any | -B--EF So Far = Any |
| Step End Control | By Time | Press >160.0 Torr | By Time | By Time |
| Maximum Step Time | 5.0 seconds | 60.0 seconds | 10.0 seconds | 128.0 seconds |
| Endpoint Selection | No Endpoint | No Endpoint | No Endpoint | No Endpoint |
| Pressure | Throttle fully open | Throttle closed | Servo 200.0 Torr | Servo 200.0 Torr |
| Pressure ramp rate | 0 steps/second | 0 steps/second | 0 Torr | 0 Torr |
| RF Power/RF2 Power | 0, 0 W | 0, 0 W | 0, 0 W | 0, 0 W |
| Heater Temperature | 480° C. (Wafer ˜431° C.) | 480° C.(Wafer ˜431° C.) | 480° C. (Wafer ˜440° C.) | 480° C. (Wafer ˜440° C.) |
| Temperature ramp | 0.00° C./sec | 0.00° C./sec | 0.00° C./sec | 0.00° C./sec |
| Heater spacing | 500 mils | 500 mils | 220 mils | 220 mils |
| Temp, Preset | 100 mWatts | 200 mWatts | 300 mWatts | 300 mWatts |
| Ligq. Inj Bypass | To Chamber | To Chamber | To Chamber | To Chamber |
| Microwave Gen. Power | 0 Watts | 0 Watts | 0 Watts | 0 Watts |
| Gas Names and Flows | O2: 4500 scc | O2: 4500 scc | O2: 4500 scc | O3: 4500 scc |
| | N2-C: 4000 scc | N2-C: 4000 scc | N2-C: 4000 scc | N2-C: 4000 scc |
| | He—C: 2000 scc | He—C: 2000 scc | He—C: 2000 scc | He—C: 2000 scc |
| | | | TEOS: 800 mgm | TEOS: 800 mgm |
| | | | | TEB: 162 mgm |
| | | | | TEPO: 145 mgm |

### SUMMARY

Accordingly, embodiments are directed to a CMOS image sensor and manufacturing method that substantially obviates one or more problems due to limitations and disadvantages of the related art.

Embodiments relate to a chemical vapor deposition method in which the pressure in a chamber is raised to a base pressure without generating particles before a main process of forming an insulation layer on a substrate in the chamber.

Additional advantages, objects, and features of the embodiments will be set forth in part in the description which follows and in part will become apparent to those having ordinary skill in the art upon examination of the following or may be learned from practical experience with the embodiments. The objectives and other advantages of the embodiments may be realized and attained by the structure particularly pointed out in the written description and claims hereof as well as the appended drawings.

To achieve these objects and other advantages and in accordance with embodiments, as broadly described herein, there is provided a chemical vapor deposition method comprising the steps of: (1) stabilizing a chamber in which a substrate is loaded on a heater by introducing a gas into the chamber; (2) increasing the pressure in the chamber to a base pressure by gradually closing a throttle valve; (3) stabilizing the base pressure in the chamber; and (4) forming an insulation film on the substrate by injecting a film forming gas into the chamber.

It is to be understood that both the foregoing general description and the following detailed description of the embodiments are exemplary and explanatory and are intended to provide further explanation of the claims.

### BRIEF DESCRIPTION OF THE DRAWINGS

FIG. 1 is a schematic view showing the gas flow state when a base pressure of a chemical vapor deposition process is regulated;

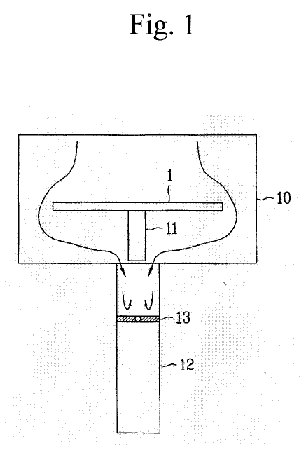

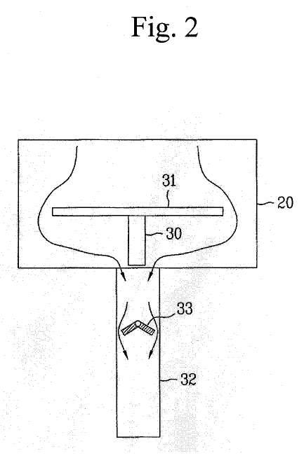

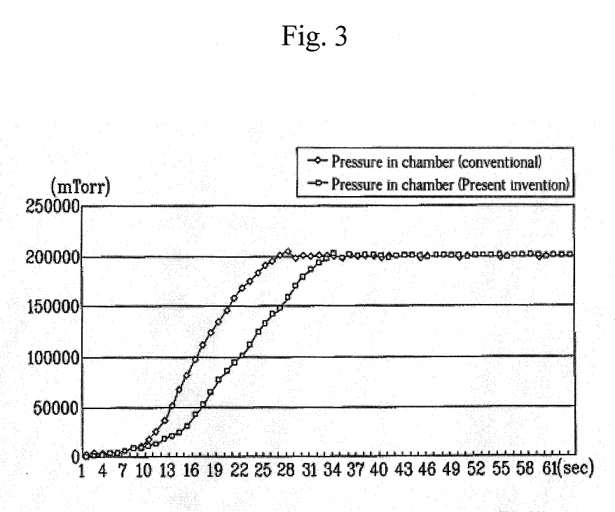

Example FIG. 2 is a schematic view showing the gas flow state when the base pressure of the chemical vapor deposition process according to embodiments is regulated; and

Example FIG. 3 is a data graph representing the values of increase of the pressure in a chamber which are measured by an hour, according to a related technology and the embodiments.

### DETAILED DESCRIPTION

FIG. 2 is a schematic view showing gas flow when the base pressure of the chemical vapor deposition process according to embodiments is regulated. FIG. 3 is a data graph representing the values of increase of the pressure in a chamber which are measured by an hour, according to a related technology and embodiments. Table 2 is an example of process conditions according to embodiments.

The chemical vapor deposition method according to embodiments relates to a process for forming an insulation film using SACVD, and as shown in FIG. 2 and Table 2, includes the steps of: loading a substrate 31 on a heater 30 in a chamber 20, (1) injecting a gas through a gas inlet on the upper side (not shown) of the process chamber 20 (1. STAB (Stability)), (2) increasing the pressure in the chamber 20 in stepped increments, at a rate of 50 steps per second, for a total of five seconds at the maximum by gradually closing a throttle valve 33 in a pumping line 32 at a lower portion of the process chamber 20 (2. R-Ramp-1), (3) increasing the pressure in the chamber 20 by closing the throttle valve 33 until the pressure in the chamber reaches 150 torr (3. P-Ramp-2), (4) stabilizing the pressure when the pressure in the chamber 20 reaches the base pressure (4. P STAB), and forming an insulation film over the substrate 31 by injecting a film forming gas into in the chamber 20.

TABLE 2

| | Step number, name | | | |
|---|---|---|---|---|
| | 1. STAB | 2. P-Ramp | 3. P STAB | 5. Dep |
| Step selection | ABCDEF So Far = Any | ABCDEF So Far = Any | ABCDEF So Far = Any | -B--EF So Far = Any |
| Step End Control | By Time | Press >160.0 Torr | By Time | By Time |
| Maximum Step Time | 5.0 seconds | 60.0 seconds | 10.0 seconds | 128.0 seconds |
| Endpoint Selection | No Endpoint | No Endpoint | No Endpoint | No Endpoint |
| Pressure | Throttle fully open | Throttle closed | Servo 200.0 Torr | Servo 200.0 Torr |
| Pressure ramp rate | 0 steps/second | 0 steps/second | 0 Torr | 0 Torr |
| RF Power/RF2 Power | 0, 0 W | 0, 0 W | 0, 0 W | 0, 0 W |
| Heater Temperature | 480° C. (Wafer ˜431° C.) | 480° C. (Wafer ˜431° C.) | 480° C. (Wafer ˜440° C.) | 480° C. (Wafer ˜440° C.) |
| Temperature ramp | 0.00° C./sec | 0.00° C./sec | 0.00° C./sec | 0.00° C./sec |
| Heater spacing | 500 mils | 500 mils | 220 mils | 220 mils |
| Temp, Preset | 100 mWatts | 200 mWatts | 300 mWatts | 300 mWatts |
| Ligq. Inj Bypass | To Chamber | To Chamber | To Chamber | To Chamber |
| Microwave Gen. Power | 0 Watts | 0 Watts | 0 Watts | 0 Watts |
| Gas Names and Flows | O2: 4500 scc | O2: 4500 scc | O2: 4500 scc | O3: 4500 scc |
| | N2-C: 4000 scc | N2-C: 4000 scc | N2-C: 4000 scc | N2-C: 4000 scc |
| | He—C: 2000 scc | He—C: 2000 scc | He—C: 2000 scc | He—C: 2000 scc |
| | | | TEOS: 800 mgm | TEOS: 800 mgm |
| | | | | TEB: 162 mgm |
| | | | | TEPO: 145 mgm |

In the SACVD process, the pressure is regulated in the chamber 20 to the base pressure of 100 to 200 torr before the main process of forming an insulation film is performed. The substrate 31 is positioned in the chamber 20, then the pressure in the chamber 20 is raised to between 200 to 750 torr.

Step (1) stabilizes the chamber. 4500 scc of O₂, 4000 scc of N₂—C, and 2000 scc of He—C are injected for one second at the maximum, with the throttle valve 33 being completely opened. The temperature of the heater is 480 degrees Celsius (the temperature of the substrate is approximately 431 degrees Celsius), and the spacing of the heater is 500 mils. The temperature preset is 100 m Watt.

In the step (2), as mentioned above, the pressure in the chamber 20 is increased for 5 seconds at the maximum by gradually closing the throttle valve 33. The pressure is increased in steps, at a rate of 50 steps per second. The other conditions are the same as in step (1).

Next, in step (3), the pressure in the chamber 20 is increased for 60 seconds at the maximum, until the pressure reaches 150 torr by gradually closing the throttle valve 33. The temperature present is 200 m Watt. If the pressure of the chamber 20 becomes 150 torr before 60 seconds elapses, step (4) is performed. The other conditions are the same as the step (2).

In the step (4), the pressure in the chamber 20 is raised 10 seconds at the maximum until the base pressure reaches 200 torr and is stabilized at that level. The temperature of the heater is 480 degrees Celsius (the temperature of the substrate is approximately 440 degrees Celsius, the spacing of the heater is 220 mils, and the temperature preset is 300 m Watt. 4500 scc of O₂, 4000 scc of N₂—C, and 2000 scc of He—C are injected. The throttle valve 33 is maintained closed throughout step (4).

Next, in step (5), 4500 scc of O₂, 4000 scc of N₂—C, 2000 scc of He—C, 800 mgm of TEOS, 162 mgm of TEB, and 145 mgm of TEPO are injected for 128 seconds at the maximum. The other conditions are the same as in step (4). TEOS, TEB, and TEPO are main gases for forming an insulation film on the substrate 31.

As mentioned above, the embodiments are characterized in that the throttle valve 33 of the pumping line 32 located at a lower portion of the chamber 20 is gradually closed when the pressure in the chamber is raised to the base pressure of 200 torr before the main process of forming the insulation film.

The process for increasing the pressure by gradually closing the throttle valve 33 is divided into two steps. In the step (2) (P-Ramp-1) according to embodiments, the throttle 33 is slowly closed by 50 steps per second. In step (3) (P-Ramp-2), the throttle valve 33 is not completely closed, so that the gas can flow downward along the pumping line 32 to prevent generation of particles due to reverse flow of the gas.

FIG. 3 is a data graph representing increasing values of pressure in a chamber versus time, according to a related technology and embodiments. It can be understood that the pressure in the chamber is increased more slowly according to embodiments than in the related technology from the comparison of the time at which the pressure in the chamber reaches the base pressure of 200 torr.

Since the pressure in the chamber is increased, with the throttle valve not being completely closed, the pressure in the chamber is increased more slowly in the embodiments than in the related technology.

The chemical vapor deposition method has the following effects.

Since the pressure in the chamber is increased by gradually closing the throttle valve of the pumping line until the pressure in the chamber reaches the base pressure, generation of particles on the substrate due to reverse flow of the gas injected into the chamber is prevented, thereby preventing a decrease in the yield.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A chemical vapor deposition method comprising:
stabilizing a chamber in which a substrate is loaded on a heater by introducing a gas into the chamber;
increasing the pressure in the chamber to a base pressure by gradually closing a throttle valve;
stabilizing the base pressure in the chamber; and
forming an insulation film on the substrate by injecting a film forming gas into the chamber.

2. A chemical vapor deposition method according to claim 1, wherein the chemical vapor deposition method is an SACVD (Sub-Atmospheric Pressure CVD) method.

3. A chemical vapor deposition method according to claim 1, wherein, in said stabilizing the chamber, O_{2,} N₂—C, and He-c are injected into the chamber for one second at the maximum, with the throttle valve being completely opened.

4. A chemical vapor deposition method according to claim 1, wherein, when said stabilizing the chamber is performed, the temperature of the heater is approximately 480 degrees Celsius, the temperature of the substrate is approximately 431 degrees Celsius, the spacing of the heater is 500 mils, and the temperature preset is 100 mWatt.

5. A chemical vapor deposition method according to claim 1, wherein said increasing the pressure comprises:
increasing the pressure in the chamber by 50 steps per second and for 5 seconds at the maximum by gradually closing the throttle valve; and
increasing the pressure in the chamber to 150 torr for 60 seconds at the maximum by gradually closing the throttle valve.

6. A chemical vapor deposition method according to claim 5, wherein, in said increasing the pressure, O_{2,} N₂—C, and He-c are injected into the chamber, the temperature of the heater is approximately 480 degrees Celsius, the temperature of the substrate is approximately 431 degrees Celsius, the spacing of the heater is 500 mils, and the temperature preset is 100 mWatt.

7. A chemical vapor deposition method according to claim 1, wherein, in said stabilizing the base pressure, the pressure in the chamber is increased for 10 seconds at the maximum to 200 torr, wherein 200 torr is the base pressure.

8. A chemical vapor deposition method according to claim 1, wherein, in said stabilizing the base pressure, O₂ gas, N₂—C gas, and He-c gas are injected into the chamber.

9. A chemical vapor deposition method according to claim 1, wherein, in said forming the insulation film, O_{2,} N₂—C, He—C, TEOS, TEB, and TEPO are injected for 128 seconds at the maximum.

10. A chemical vapor deposition method according to claim 1, wherein, in said stabilizing the base pressure and said forming the insulation film, the temperature of the heater is approximately 480 degrees Celsius, the temperature of the substrate is approximately 440 degrees Celsius, the spacing of the heater is 220 mils, and the temperature preset is 300 mWatt.

11. A chemical vapor deposition method according to claim 1, wherein said increasing the pressure comprises gradually closing a throttle valve prevents a reverse flow of gas which carries particles past the throttle and into the chamber.

12. A chemical vapor deposition method according to claim 11, wherein the particles are smaller than 0.1 μm in diameter.

13. A chemical vapor deposition method according to claim 5, wherein said increasing the pressure comprises gradually closing a throttle valve prevents a reverse flow of gas which carries particles past the throttle and into the chamber.
